(19) United States
(12) Patent Application Publication
(10) Pub. No.: US 2026/0331967 A1
(43) Pub. Date: Oct. 22, 2026

(54) Movable Body Power Feeding Facility

(71) Applicant: Daifuku Co., Ltd., Osaka-shi (JP)

(72) Inventor: Masaaki Yamamoto, Hinocho (JP)

(21) Appl. No.: 19/650,462

(22) Filed: Apr. 17, 2026

(30) Foreign Application Priority Data
Apr. 18, 2025 (JP) 2025-068589

(51) Int. Cl. H02J 50/90; H02J 50/80; H10P 72/30; H02J 50/10

(52) U.S. Cl. CPC H02J 50/90; H02J 50/80; H10P 72/3221; H02J 50/10

(57) ABSTRACT

A movable body power feeding facility includes power feeding lines disposed along a movement path of a movable body to supply power to the movable body, and a plurality of power supply devices to supply power to the power feeding lines. The movement path has a plurality of power feeding areas. A target power supply device switches between supply modes of supplying power to the power feeding line in the target power feeding area, based on the presence/absence of the movable body in the target power feeding area. The supply modes include a first supply mode of supplying a first set power in response to the movable body being present in the target power feeding area, and a second supply mode of supplying a second set power that is smaller than the first set power, in response to the movable body not being present in the target power feeding area.

### CROSS-REFERENCE TO RELATED APPLICATION

This application claims priority to Japanese Patent Application No. 2025-068589 filed Apr. 18, 2025, the disclosure of which is hereby incorporated by reference in its entirety.

### BACKGROUND OF THE INVENTION

### 1. Field of the Invention

The present invention relates to a movable body power feeding facility including power feeding lines disposed along a movement path of a movable body and configured to supply power to the movable body, and a plurality of power supply devices connected to the power feeding lines and configured to supply power to the power feeding lines.

### 2. Description of Related Art

JP 2002-67747A discloses an example of such a power feeding facility. In the following, the reference numerals described in JP 2002-67747A are cited in parentheses in the description of the related art.

In the power feeding facility disclosed in JP 2002-67747A, a plurality of power feeding lines (47) are disposed along a movement path (B) of a plurality of movable bodies (V). A power supply device (M) is connected to each of the plurality of power feeding lines (47). This enables each of the plurality of movable bodies (V) to move along the movement path (B) using power supplied from the power feeding line (47) in close proximity thereto.

In the power feeding facility disclosed in JP 2002-67747A, the power supplied from the power supply devices (M) to the corresponding feeding lines (47) is set based on the maximum number of movable bodies (V) that can be located in one power feeding area in which each of the power feeding lines (47) is disposed along the movement path (B). Accordingly, an excessive amount of power may be supplied from the power supply devices (M) to the power feeding lines (47), and this results in an increase in the power consumed in the power feeding facility.

### SUMMARY OF THE INVENTION

In view of the above-described circumstances, it is desirable to realize a movable body power feeding facility capable of keeping consumed power small.

A technique for solving the above-described problem is as follows.

A movable body power feeding facility including:
power feeding lines disposed along a movement path of a movable body and configured to supply power to the movable body; and
a plurality of power supply devices respectively connected to the power feeding lines and configured to supply power to the respective power feeding lines,
the movement path being divided into a plurality of power feeding areas,
the power feeding lines being respectively located in the plurality of power feeding areas and configured to receive supply of power from the corresponding power supply devices,
with a target power feeding area being one of the plurality of power feeding areas, and a target power supply device being the power supply device that supplies power to the power feeding line in the target power feeding area,
the target power supply device being configured to switch between a plurality of supply modes of supplying power to the power feeding line in the target power feeding area, based on presence and absence of the movable body in the target power feeding area, and
the plurality of supply modes including
   a first supply mode of supplying a first set power in response to the movable body being present in the target power feeding area, and
   a second supply mode of supplying a second set power smaller than the first set power, in response to the movable body not being present in the target power feeding area.

With this configuration, in a situation where the movable body is not present in a power feeding area, and hence the necessity for power supply is low, the power supply device supplying power to the power feeding line in that power feeding area executes the second supply mode, thus making it possible to reduce the supplied power as compared to that in a case where the movable body is present in the power feeding area. Therefore, the consumed power can be kept small.

Further features and advantages of the present disclosure will become apparent from the following description of illustrative and non-limiting embodiments with reference to the drawings.

### BRIEF DESCRIPTION OF THE DRAWINGS

FIG. 1 is a plan view of an article transport facility including a movable body power feeding facility.

FIG. 2 is a front view of a movable body.

FIG. 3 is a schematic diagram showing a configuration of the movable body power feeding facility.

FIG. 4 is a diagram showing changes in a control parameter.

FIG. 5 is a flowchart of first processing.

FIG. 6 is a flowchart of second processing.

FIG. 7 is a diagram showing changes in a control parameter in other embodiments.

### DESCRIPTION OF THE INVENTION

A movable body power feeding facility is a facility for ensuring motive power for a movable body that moves along a movement path. The movable body may serve to transport articles. The movable body power feeding facility may be applied to an article transport facility in which such a movable body is used. Hereinafter, an embodiment of the movable body power feeding facility will be described taking, as an example, a case where the movable body power feeding facility is applied to an article transport facility.

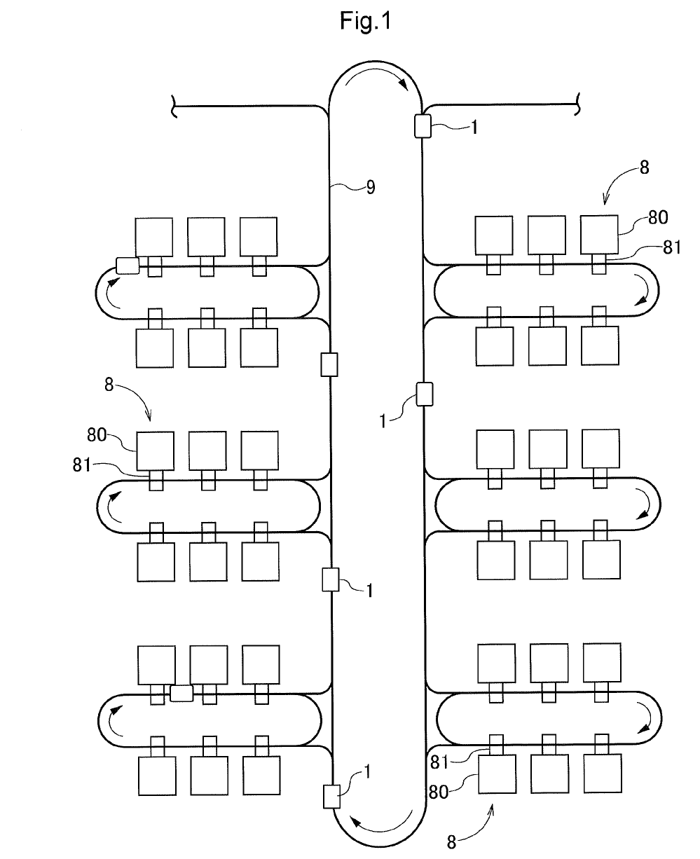

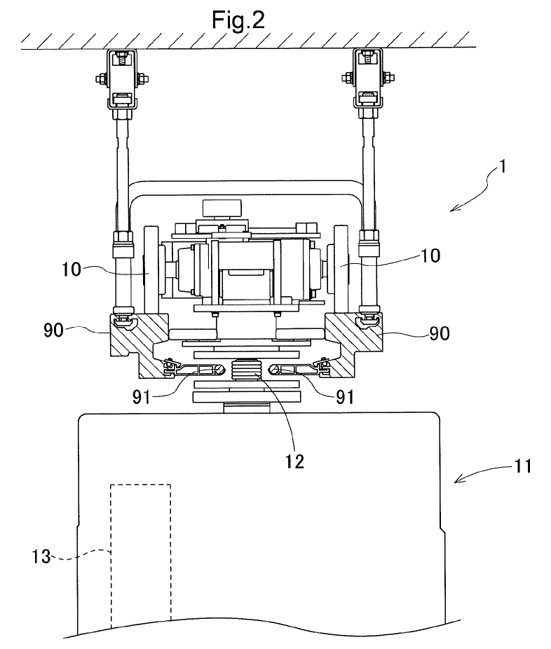

As shown in FIG. 1, the article transport facility includes a movable body 1 that transports an article, travel rails 90 (see also FIG. 2) installed near the ceiling of the facility and constituting a movement path 9 of the movable body 1, and transfer target locations 8 where the article is transferred to and from the movable body 1. That is, the article transport facility in this example is configured as a ceiling transport facility that transports the article near the ceiling.

A processing device 80 that performs processing on the article, and a support platform 81 that is disposed adjacent to the processing device 80 and that supports the article, are provided at each of the transfer target locations 8. In the present embodiment, the movable body 1 transports an article that has not yet been subjected to the processing performed by the processing device 80 to the support platform 81, and transports an article that has been subjected to the processing performed by the processing device 80 from the support platform 81 to a designated transport destination.

For example, the article is a container that stores a processing target object to be subjected to the processing performed by the processing device 80, and the above-described "processing on the article" means processing on the processing target object stored in the article. The article may be a wafer storage container (a so-called FOUP: Front Opening Unified Pod) that stores a wafer, or a reticle storage container (a so-called reticle pod) that houses a reticle. In a case where the article is a FOUP, the processing target object is a wafer. In a case where the article is a reticle pod, the processing target object is a reticle.

As shown in FIG. 2, the movable body power feeding facility includes power feeding lines 91 that are disposed along the movement path 9 and that supply power to the movable body 1. In the present embodiment, the movement path 9 is configured with a pair of travel rails 90. The power feeding lines 91 are disposed along each of the travel rails 90.

In the present embodiment, the movable body 1 includes travel wheels 10 that roll on the travel rails 90, a body section 11 capable of housing an article that is being transported, and a power receiving device 12.

The power receiving device 12 is a device that receives power in a contactless manner from the power feeding lines 91. The power receiving device 12 includes a pick-up coil. Alternating current power is induced in the pick-up coil by a magnetic field generated around the power feeding line 91 to which a current is supplied. The alternating current power is converted into direct current by a power receiving circuit of the power receiving device 12, the power receiving circuit including a rectifier circuit, a smoothing capacitor, and so forth, and the direct current is supplied to a travel motor of the movable body 1 and various actuators, and so forth. The power received by the power receiving device 12 is used as at least part of a motive power source of the movable body 1.

In the present embodiment, the movable body 1 has a power storage device 13 mounted therein, and can use the power stored in the power storage device 13 as a motive power source. The movable body 1 is capable of moving along the movement path 9 by using the power obtained from the power feeding lines 91 and the power stored in the power storage device 13. In this example, the movable body 1 is configured to mainly use the power obtained from the power feeding lines 91, and accessorily use the power stored in the power storage device 13. Note that examples of the power storage device 13 include a battery and an electric double-layer capacitor (EDLC).

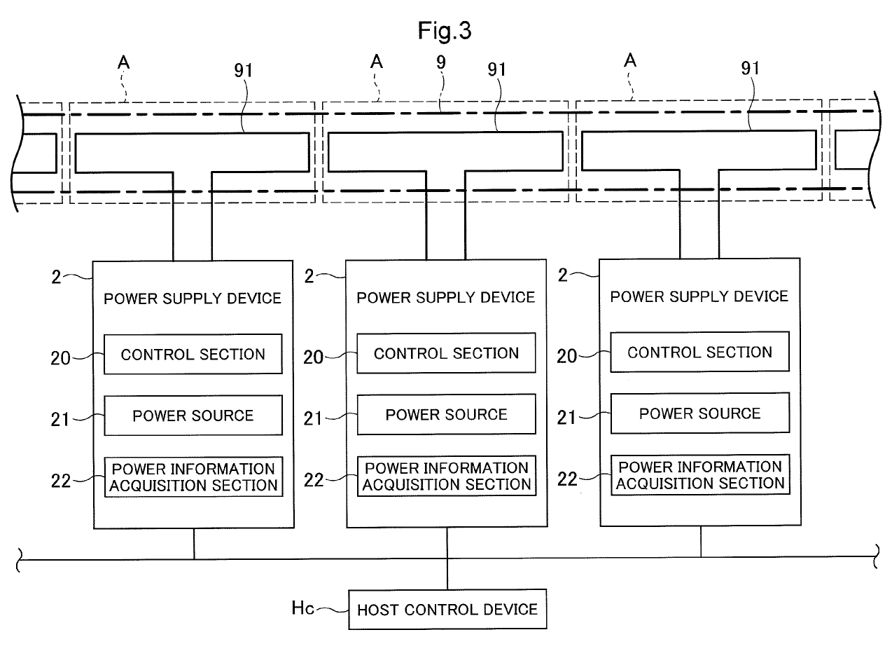

FIG. 3 is a schematic diagram of the movable body power feeding facility.

As shown in FIG. 3, the movement path 9 is divided into a plurality of power feeding areas A. The movable body power feeding facility includes a plurality of power supply devices 2 that are connected to the power feeding lines 91 and that supply power to the power feeding lines 91. The power feeding lines 91 respectively located in the plurality of power feeding areas A are configured to receive supply of power from the corresponding power supply devices 2. Each of the power feeding areas A is served by one or more power supply devices 2. In the example shown in FIG. 3, one power supply device 2 serves one power feeding area A.

In the present embodiment, the movable body power feeding facility includes a host control device Hc that performs overall control of the facility. The host control device Hc is configured to communicate with each of the plurality of movable bodies 1. For example, the host control device Hc manages a transport schedule of articles in the article transport facility, and issues a transport command to each of the movable bodies 1 in accordance with the schedule. The host control device Hc is configured to communicate with each of the plurality of power supply devices 2. For example, the host control device Hc is configured to transmit information relating to each of the movable bodies 1 to any given power supply device 2.

Each power supply device 2 includes a control section 20 and a power source 21. The power source 21 is a source of power supplied to the corresponding power feeding line 91, and is connected to the power feeding line 91. The control section 20 includes a CPU, a memory, and so forth. The control section 20 mainly serves to control the power supplied from the power source 21 to the power feeding line 91.

In the present embodiment, each power supply device 2 includes a power information acquisition section 22 that acquires information about the remaining amount of power in the power storage device 13 mounted in the movable body 1. For example, the power supply device 2 is configured to communicate with the movable body 1, and is configured to directly acquire the information about the remaining amount of power in the power storage device 13 from the movable body 1. However, the power supply device 2 may be configured to acquire the information about the remaining amount of power in the power storage device 13 mounted in the movable body 1, via the host control device Hc configured to communicate with the movable body 1. The above-described configuration enables each power supply device 2 to have the information about the remaining amount of power of the movable body 1 that is scheduled to enter the power feeding area A served by the power supply device 2.

In the following description, a target power feeding area A is defined as one of the plurality of power feeding areas A. In addition, a target power supply device 2 is defined as a power supply device 2 that supplies power to the power feeding line 91 of the target power feeding area A.

The target power supply device 2 is configured to switch a supply mode of power to the power feeding line 91 of the target power feeding area A, based on the presence or absence of the movable body 1 in the target power feeding area A.

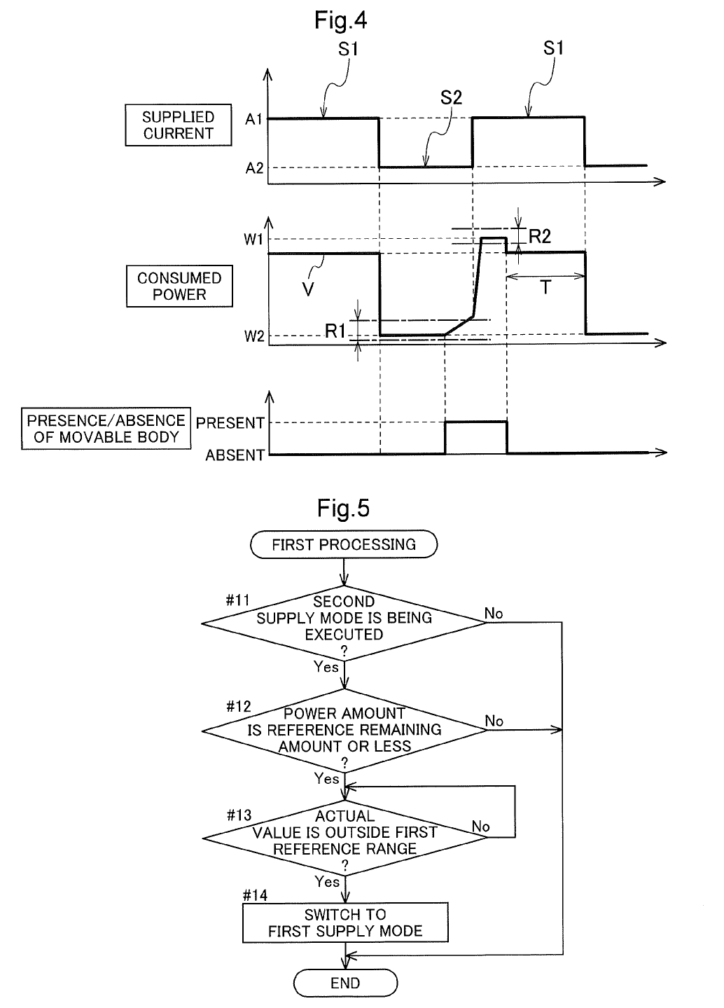

As shown in FIG. 4, supply modes of power that are executable by the target power supply device 2 include a first supply mode S1 in which supplied power is set to a first set power in response to the movable body 1 being present in the target power feeding area A, and a second supply mode S2 in which supplied power is set to a second set power that is smaller than the first set power in response to the movable body 1 not being present in the target power feeding area A.

Accordingly, the target power supply device 2 can suppress the supply of power in a case where the movable body 1 is not present in the target power feeding area A, as compared with a case where the movable body 1 is present in the target power feeding area A. Therefore, this contributes to power saving.

In the present embodiment, the target power supply device 2 adjusts the supplied power by adjusting the current supplied to the power feeding line 91 (hereinafter referred to as the "supplied current"). However, the present disclosure is not limited thereto, and the adjustment of the supplied power may be achieved by voltage adjustment.

In this example, a first current A1 is supplied in the first supply mode S1. A second current A2 that is smaller than the first current A1 is supplied in the second supply mode S2. The second current A2 is at least greater than zero.

The target power supply device 2 determines the presence or absence of the movable body 1 in the target power feeding area A, based on a change in the impedance of the power feeding line 91 of the target power feeding area A. In this example, the presence or absence of the movable body 1 is determined based on the value of a target parameter. The term "target parameter" as used herein refers to a parameter that is included among control parameters of the power supply device 2 and that changes in response to change in the impedance of the power feeding line 91. Examples of the target parameter include consumed power, a voltage, and a duty ratio (duty ratio of pulse voltage).

In the present embodiment, consumed power [kilowatt (kW)] is used as the target parameter. The movable body 1 that has entered the target power feeding area A starts receiving power based on the current supplied from the target power supply device 2 to the power feeding line 91. Accordingly, the impedance changes, and the consumed power serving as the target parameter increases. A phenomenon reverse to the above-described phenomenon occurs in response to the movable body 1 exiting the target power feeding area A, and the consumed power as the target parameter decreases. Based on such a change in the target parameter, the target power supply device 2 determines the presence or absence of the movable body 1 in the target power feeding area A. In this example, the target power supply device 2 is configured to perform feedback control in such a manner as to maintain a desired current, thereby directly determining the presence or absence of the movable body 1 in the target power feeding area A by itself.

As described above, it is possible not only to detect a change in impedance in the first supply mode S1, but also to detect a change in impedance in the second supply mode S2, which is a power saving mode, since a current that is at least greater than zero is supplied to the power feeding line 91. This makes it possible to determine the presence or absence of the movable body based on the impedance as described above.

The target power supply device 2 sets a first reference range R1 based on the value of the target parameter in a state in which the movable body 1 is not present in the target power feeding area A. In this example, consumed power (e.g., second consumed power W2) in a state in which the movable body 1 is not present in the target power feeding area A, to which the second current A2 is supplied, has a value greater than 0 [kW] by a predetermined amount, and a predetermined range including this value is set as the first reference range R1.

The target power supply device 2 determines that the movable body 1 is not present in the target power feeding area A in response to an actual value V of the target parameter being within the first reference range R1, and determines that the movable body 1 is present in the target power feeding area A in response to the actual value V being outside the first reference range R1. As shown in FIG. 4, in a case where the movable body 1 has entered the target power feeding area A, or in other words, in a case where the determination of the presence or absence of the movable body has changed to "PRESENT" on the bottom graph in FIG. 4, the actual value V of the consumed power increases to a value outside the first reference range R1. The target power supply device 2 determines that the movable body 1 is present in the target power feeding area A in response to the actual value V of the consumed power being a value outside the first reference range R1.

This determination of the presence or absence of the movable body 1 based on the first reference range R1 is performed for switching the supply mode of power to the first supply mode S1. Accordingly, the determination of the presence or absence of the movable body 1 based on the first reference range R1 is performed during execution of the second supply mode S2.

The target power supply device 2 switches the supply mode of power to the first supply mode S1 in response to determining that the movable body 1 is present in the target power feeding area A. In this example, the supplied current is increased. For example, the supplied current is increased from the second current A2 to the first current A1.

The target power supply device 2 sets a second reference range R2 based on the value of the target parameter in a state in which the movable body 1 is present in the target power feeding area A. In this example, a predetermined range including a value of consumed power (e.g., first consumed power W1) in a state in which the movable body 1 is present in the target power feeding area A, to which the first current A1 is supplied, is set as the second reference range R2.

The target power supply device 2 determines that the movable body 1 is present in the target power feeding area A in response to the actual value V of the target parameter being within the second reference range R2, and determines that the movable body 1 is not present in the target power feeding area A in response to the actual value V being outside the second reference range R2. As shown in FIG. 4, in a case where the movable body 1 has exited the target power feeding area A, or in other words, in a case where the determination of the presence or absence of the movable body has changed to "ABSENT" on the bottom graph in FIG. 4, the actual value V of the consumed power decreases to a value outside the second reference range R2. The target power supply device 2 determines that the movable body 1 is not present in the target power feeding area A in response to the actual value V of the consumed power being a value outside the second reference range R2.

This determination of the presence or absence of the movable body 1 based on the second reference range R2 is performed for switching the supply mode of power to the second supply mode S2. Accordingly, the determination of the presence or absence of the movable body 1 based on the second reference range R2 is performed during execution of the first supply mode S1.

The target power supply device 2 switches the supply mode of power to the second supply mode S2 in response to determining that the movable body 1 is not present in the target power feeding area A. In this example, the supplied current is reduced. For example, the supplied current is reduced from the first current A1 to the second current A2.

In the present embodiment, the target power supply device 2 immediately switches the supply mode from the second supply mode S2 to the first supply mode S1 in response to the actual value V of the target parameter shifting from a value within the first reference range R1 to a value outside the first reference range R1.

As described above, the movable body 1 moves along the movement path 9 by mainly using the power obtained from the power feeding line 91. Therefore, the movable body 1 may stop due to insufficient motive power in a case where sufficient power is not supplied to the target power feeding area A that the movable body 1 has entered, because the target power supply device 2 is executing the second supply mode S2 in which the supplied power is small. However, in a case where the presence of the movable body 1 in the target power feeding area A is detected as in the present embodiment, or in other words, in a case where the entry of the movable body 1 into the target power feeding area A is detected, the target power supply device 2 immediately switches the supply mode from the second supply mode S2 to the first supply mode S1, thus making it possible to appropriately supply power to the movable body 1 immediately after the movable body 1 has entered the target power feeding area A.

Even if the supply of power to the movable body 1 is delayed, the movable body 1 according to the present embodiment is capable of moving along the movement path 9 by using the power stored in the power storage device 13, and therefore can be prevented from stopping due to insufficient motive power until power is supplied thereto. That is, in the present embodiment, the movable body 1 is configured to move in the target power feeding area A by using the power stored in the power storage device 13 in a case where the power from the power feeding line 91 in the target power feeding area A is insufficient.

In the present embodiment, in the case where the actual value V has shifted from a value within the second reference range R2 to a value outside the second reference range R2, the target power supply device 2 switches the supply mode from the first supply mode S1 to the second supply mode S2 after a preset set time period T has elapsed.

In the case where the movable body 1 is not present in the target power feeding area A, there is no problem in continuing the first supply mode S1 in which the supplied power is large. Rather, it is not preferable to execute the second supply mode S2 in which the supplied power is small even though the movable body 1 is present in the target power feeding area A, because the movable body 1 may stop due to insufficient motive power. With the above-described configuration, in a case where the movable body 1 exits the target power feeding area A, switching from the first supply mode S1 to the second supply mode S2 can be performed after waiting for an elapse of the set time period T and reliably determining the exit of the movable body 1. Therefore, it is likely to avoid a situation where the second supply mode S2, in which the supplied power is small, is executed while the movable body 1 is present in the target power feeding area A.

In the present embodiment, in determining the presence or absence of the movable body 1 in the target power feeding area A, the target power supply device 2 determines that the movable body 1 is not present in the target power feeding area A in a case where the power of the power storage device 13 mounted in the movable body 1 has a remaining amount that is larger than a predetermined reference remaining amount. That is, such a movable body 1 is determined to not be present in the target power feeding area A under the control performed by the target power supply device 2, despite the movable body 1 being actually present in the target power feeding area A. As a result, the supply mode of power is set to the second supply mode S2. In a case where the power storage device 13 stores sufficient power, the movable body 1 can move along the movement path 9 by mainly using that power. Therefore, even if the second supply mode S2, in which the supplied power is small, is being executed, the movable body 1 can appropriately move along the movement path 9. In addition to this, power saving can be achieved since the second supply mode S2 is being executed. The "reference remaining amount" can be set freely, and is preferably set, for example, in the range from 60% to 80% of the power that can be stored by the power storage device 13. The target power supply device 2 may check the remaining amount of the power storage device 13 for one movable body 1 alone as a target, or a plurality of movable bodies 1 at a time as targets.

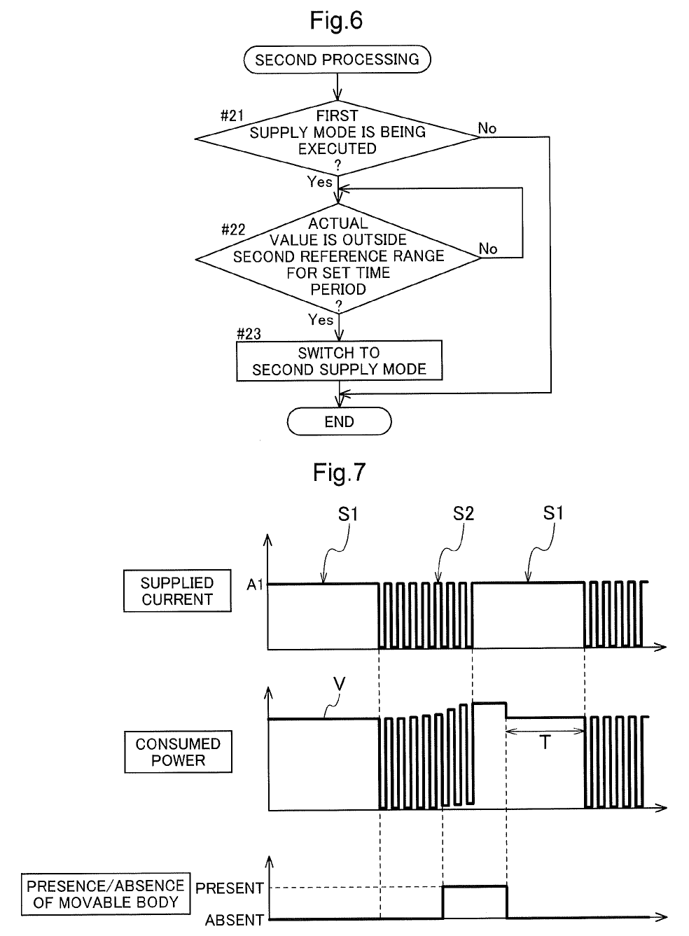

In the present embodiment, the power supply device 2 is configured to execute first processing and second processing. FIG. 5 is a flowchart illustrating a procedure of the first processing. FIG. 6 is a flowchart illustrating a procedure of the second processing.

As shown in FIG. 5, the first processing is processing for switching the supply mode of power to the first supply mode S1, or processing for maintaining the first supply mode S1. That is, execution of the first processing brings the supply mode of power into the first supply mode S1. However, this is not necessarily applicable in a case where the movable body 1 entering the target power feeding area A is provided with a power storage device 13 storing an amount of power that is larger than the reference remaining amount.

In the first processing, first, whether the second supply mode S2 is being executed is determined (#11). If the second supply mode S2 is not being executed (#11: No), this indicates that the first supply mode S1 is being executed, and therefore the routine ends.

If it is determined that the second supply mode S2 is being executed (#11: Yes), whether the remaining amount of power in the power storage device 13 mounted in the target movable body 1 is less than or equal to the reference remaining amount is determined (#12). If the amount of power is not less than or equal to the reference remaining amount (#12: No), or in other words, if the amount of power stored in the power storage device 13 is larger than the reference remaining amount, this indicates that the movable body 1 is capable of moving the movement path 9 by using that power, and there is no problem in continuing the second supply mode S2. Accordingly, the routine ends, with the second supply mode S2 kept continued.

If the remaining amount of power in the power storage device 13 mounted in the target movable body 1 is less than or equal to the reference remaining amount (#12: Yes), whether the actual value V of the target parameter is outside the first reference range R1 is determined (#13). If it is determined that the actual value V is outside the first reference range R1 (#13: Yes), the supply mode of power is switched from the second supply mode S2 to the first supply mode S1 (#14), and then the routine ends. Note that step 13 is repeated until the determination becomes "Yes".

As shown in FIG. 6, the second processing is processing for switching the supply mode of power to the second supply mode S2, or processing for maintaining the second supply mode S2. That is, execution of the second processing brings the supply mode of power into the second supply mode S2.

In the second processing, first, whether the first supply mode S1 is being executed is determined (#21). If the first supply mode S1 is not being executed (#21: No), this indicates that the second supply mode S2 is being executed, and therefore the routine ends.

If it is determined that the first supply mode S1 is being executed (#21: Yes), whether the actual value V of the target parameter is outside the second reference range R2 for the set time period T is determined (#22). If it is determined that the actual value V is outside the second reference range R2 for the set time period T (#22: Yes), the supply mode of power is switched from the first supply mode S1 to the second supply mode S2 (#23), and then the routine ends. Note that step 22 is repeated until the determination becomes "Yes".

### Other Embodiments

Next, other embodiments will be described.

(1) The above embodiment has described an example in which the target power supply device 2 supplies the first current A1 in the first supply mode S1, and supplies the second current A2, which is smaller than the first current A1, in the second supply mode S2. Accordingly, the amount of power supplied is kept smaller in the second supply mode S2 than in the first supply mode S1. However, as shown in FIG. 7, for example, the target power supply device 2 may intermittently supply power to the target power feeding area A in the second supply mode S2. The amount of power supplied in the second supply mode S2 may also be kept smaller than in the first supply mode S1 in this manner. In this example, in the second supply mode S2, the target power supply device 2 intermittently supplies a first current A1 having the same magnitude as the current supplied in the first supply mode S1. Unlike such an example, the target power supply device 2 may be configured to intermittently supply a current smaller than the first current A1, which is supplied in the first supply mode S1, in the second supply mode S2.
(2) The above embodiment has described an example in which the movement path 9 of the movable body 1 is configured with the travel rails 90 installed near the ceiling of the facility. However, the present disclosure is not limited to such an example. The travel rails 90 constituting the movement path 9 may be installed along the floor surface of the facility.
(3) The above embodiment has described an example in which the movable body 1 has the power storage device 13 mounted therein. However, the present disclosure is not limited to such an example. A movable body 1 having no power storage device 13 mounted therein may be present in the facility.
(4) The above embodiment has described an example in which the target power supply device 2 directly determines the presence or absence of the movable body 1 in the target power feeding area A by itself. However, the present disclosure is not limited to such an example. A host control device Hc capable of acquiring information regarding a change in impedance in the target power feeding area A may determine the presence or absence of the movable body 1 in the target power feeding area A. In this case, the determination information determined by the host control device Hc is transmitted from the host control device Hc to the target power supply device 2, and the target power supply device 2 performs final determination based on the transmitted determination information.

Note that the present disclosure is not limited to the above-described examples, and the host control device Hc may determine the presence or absence of the movable body 1 in the target power feeding area A, based on position information of the movable body 1.

(5) Note that the configurations disclosed in the embodiments described above are applicable in combination with configurations disclosed in other embodiments as long as no inconsistency arises. With regard to the other configurations as well, the embodiments disclosed herein are illustrative in all respects. Therefore, various modifications and alterations may be made as appropriate without departing from the gist of the present disclosure.

### Summary of the Present Embodiment

The present embodiment is summarized below.

A movable body power feeding facility including:
power feeding lines disposed along a movement path of a movable body and configured to supply power to the movable body; and
a plurality of power supply devices respectively connected to the power feeding lines and configured to supply power to the respective power feeding lines,
the movement path being divided into a plurality of power feeding areas,
the power feeding lines being respectively located in the plurality of power feeding areas and configured to receive supply of power from the corresponding power supply devices,
with a target power feeding area being one of the plurality of power feeding areas, and a target power supply device being the power supply device that supplies power to the power feeding line in the target power feeding area,
the target power supply device being configured to switch between a plurality of supply modes of supplying power to the power feeding line in the target power feeding area, based on presence and absence of the movable body in the target power feeding area, and
the plurality of supply modes including
   a first supply mode of supplying a first set power in response to the movable body being present in the target power feeding area, and
   a second supply mode of supplying a second set power smaller than the first set power, in response to the movable body not being present in the target power feeding area.

With this configuration, in a situation where the movable body is not present in the power feeding area, and hence the necessity for power supply is low, the power supply device supplying power to the power feeding line in the power feeding area executes the second supply mode, thus making it possible to reduce the supplied power as compared to that in a case where the movable body is present in the power feeding area. Therefore, the consumed power can be kept small.

It is preferable that the target power supply device determines presence or absence of the movable body in the target power feeding area based on a change in an impedance of the power feeding line in the target power feeding area.

This configuration makes it possible to easily determine the presence or absence of the movable body in the target power feeding area.

It is preferable that the target power supply device sets a first reference range based on a value of a target parameter in a state in which the movable body is not present in the target power feeding area, the target parameter being a parameter that is included among control parameters of the plurality of power supply devices and that changes in accordance with a change in the impedance of the corresponding power feeding line,

the target power supply device determines that the movable body is not present in the target power feeding area in response to an actual value of the target parameter being within the first reference range, and

the target power supply device determines that the movable body is present in the target power feeding area in response to the actual value being outside the first reference range.

With this configuration, a parameter that is relatively easy to measure can be freely selected, and the presence or absence of the movable body in the target power feeding area can be determined based on that parameter.

It is preferable that the target power supply device sets a second reference range based on a value of the target parameter in a state in which the movable body is present in the target power feeding area,

the target power supply device immediately switches from the second supply mode to the first supply mode in response to the actual value shifting from a value within the first reference range to a value outside the first reference range, and

in response to the actual value shifting from a value within the second reference range to a value outside the second reference range, the target power supply device switches from the first supply mode to the second supply mode after a preset set time period elapses.

With this configuration, switching from the second supply mode in which the supplied power is small to the first supply mode in which the supplied power is large can be performed quickly in a case where the movable body enters the target power feeding area. Accordingly, power can be appropriately supplied to the movable body. On the other hand, in a case where the movable body exits the target power feeding area, switching from the first supply mode to the second supply mode can be performed after waiting for an elapse of the set time period and reliably determining the exit of the movable body. In this manner, this configuration facilitates appropriate supply of the required amount of power to the movable body present in the target power feeding area.

It is preferable that the target power supply device intermittently supplies power to the target power feeding area in the second supply mode.

With this configuration, the supplied power in the second supply mode can be made smaller than the supplied power in the first supply mode by relatively simple control.

It is preferable that the movable body is provided with a power storage device and configured to use power stored in the power storage device as a motive power source, and

the movable body moves in the target power feeding area using the power stored in the power storage device in a case where an amount of power supplied from the power feeding line in the target power feeding area is insufficient.

This configuration enables the movable body to move using the power of the power storage device mounted therein even in a case where the power supplied from the power feeding line is insufficient. Accordingly, the movable body can appropriately continue the movement, for example, even in a case where the timing of the switch from the second supply mode to the first supply mode is delayed.

It is preferable that each of the plurality of power supply devices includes a power information acquisition section configured to acquire information about a remaining amount of power in the power storage device provided in the movable body, and

in determining presence or absence of the movable body in the target power feeding area, the target power supply device determines that the movable body is not present in the target power feeding area in response to the remaining amount of power in the power storage device provided in the movable body being larger than a predetermined reference remaining amount.

This configuration makes it possible to determine the necessity for power supply in the power feeding area in accordance with the remaining amount of power in the power storage device mounted in the movable body. Accordingly, it is possible to not supply power to the power feeding area in a situation where the necessity for power supply is low, thus achieving an increased power saving.

The technique according to the present disclosure is applicable to a movable body power feeding facility including power feeding lines disposed along a movement path of a movable body and configured to supply power to the movable body, and a plurality of power supply devices connected to the power feeding lines and configured to supply power to the power feeding lines.

What is claimed is:

1. A movable body power feeding facility comprising:
power feeding lines disposed along a movement path of a movable body and configured to supply power to the movable body; and
a plurality of power supply devices respectively connected to the power feeding lines and configured to supply power to the respective power feeding lines, and
wherein:
the movement path is divided into a plurality of power feeding areas,
the power feeding lines are respectively located in the plurality of power feeding areas and configured to receive supply of power from the corresponding power supply devices,
with a target power feeding area being one of the plurality of power feeding areas, and a target power supply device being the power supply device that supplies power to the power feeding line in the target power feeding area, the target power supply device is configured to switch between a plurality of supply modes of supplying power to the power feeding line in the target power feeding area, based on presence and absence of the movable body in the target power feeding area, and
the plurality of supply modes comprise:
a first supply mode of supplying a first set power in response to the movable body being present in the target power feeding area, and
a second supply mode of supplying a second set power smaller than the first set power, in response to the movable body not being present in the target power feeding area.

2. The movable body power feeding facility according to claim 1,
wherein the target power supply device determines presence or absence of the movable body in the target power feeding area based on a change in an impedance of the power feeding line in the target power feeding area.

3. The movable body power feeding facility according to claim 2, wherein:
the target power supply device sets a first reference range based on a value of a target parameter in a state in which the movable body is not present in the target power feeding area, the target parameter being a parameter that is included among control parameters of the plurality of power supply devices and that changes in accordance with a change in the impedance of the corresponding power feeding line,
the target power supply device determines that the movable body is not present in the target power feeding area in response to an actual value of the target parameter being within the first reference range, and
the target power supply device determines that the movable body is present in the target power feeding area in response to the actual value being outside the first reference range.

4. The movable body power feeding facility according to claim 3, wherein:
the target power supply device sets a second reference range based on a value of the target parameter in a state in which the movable body is present in the target power feeding area,
the target power supply device immediately switches from the second supply mode to the first supply mode in response to the actual value shifting from a value within the first reference range to a value outside the first reference range, and
in response to the actual value shifting from a value within the second reference range to a value outside the second reference range, the target power supply device switches from the first supply mode to the second supply mode after a preset set time period elapses.

5. The movable body power feeding facility according to claim 1,
wherein the target power supply device intermittently supplies power to the target power feeding area in the second supply mode.

6. The movable body power feeding facility according to claim 1,
wherein the movable body is provided with a power storage device and configured to use power stored in the power storage device as a motive power source, and
wherein the movable body moves in the target power feeding area using the power stored in the power storage device in a case where an amount of power supplied from the power feeding line in the target power feeding area is insufficient.

7. The movable body power feeding facility according to claim 6,
wherein each of the plurality of power supply devices comprises a power information acquisition section configured to acquire information about a remaining amount of power in the power storage device provided in the movable body, and
wherein in determining presence or absence of the movable body in the target power feeding area, the target power supply device determines that the movable body is not present in the target power feeding area in response to the remaining amount of power in the power storage device provided in the movable body being larger than a predetermined reference remaining amount.
